(19) United States
(12) Patent Application Publication
(10) Pub. No.: US 2013/0095661 A1
(43) Pub. Date: Apr. 18, 2013

(54) CMP METHOD, CMP APPARATUS AND METHOD OF MANUFACTURING SEMICONDUCTOR DEVICE

(71) Applicants: Akifumi GAWASE, Yokohama-shi (JP); Yukiteru Matsui, Yokohama-shi (JP); Gaku Minamihaba, Yokohama-shi (JP); Hajime Eda, Yokohama-shi (JP)

(72) Inventors: Akifumi GAWASE, Yokohama-shi (JP); Yukiteru Matsui, Yokohama-shi (JP); Gaku Minamihaba, Yokohama-shi (JP); Hajime Eda, Yokohama-shi (JP)

(21) Appl. No.: 13/428,163

(22) Filed: Mar. 23, 2012

(30) Foreign Application Priority Data
Oct. 12, 2011 (JP) 2011-224757

(51) Int. Cl. H01L 21/302; B24B 53/017; B24B 37/015; B24B 37/013; B24B 37/07

(52) U.S. Cl. 438/693; 451/1; 451/11; 257/E21.23

(57) ABSTRACT

According to one embodiment, a CMP method includes starting a polishing of a silicon oxide film by using a slurry including a silicon oxide abrasive and a polishing stopper film including a silicon nitride film, and stopping the polishing when the polishing stopper is exposed. The slurry includes a first water-soluble polymer with a weight-average molecular weight of 50000 or more and 5000000 or less, and a second water-soluble polymer with a weight-average molecular weight of 1000 or more and 10000 or less.

### CROSS-REFERENCE TO RELATED APPLICATIONS

This application is based upon and claims the benefit of priority from prior Japanese Patent Application No. 2011-224757, filed Oct. 12, 2011, the entire contents of which are incorporated herein by reference.

### FIELD

Embodiments described herein relate generally to a CMP method, a CMP apparatus and a method of manufacturing a semiconductor device.

### BACKGROUND

In order to solve a problem that the surface of a polished film easily suffers polishing scratches in planarization of a silicon oxide film (film to be polished) by chemical mechanical polishing (CMP), there is a technique using a silicon oxide abrasive as an abrasive to be contained in the slurry in place of a cerium oxide abrasive.

According to this technique, it is possible, by further introducing a water-soluble polymer into the slurry, to prevent the polishing rate of the silicon oxide film from being lowered by the use of the silicon oxide abrasive.

However, when the above-mentioned technique is used, it is difficult to secure a polishing selectivity ratio of the silicon oxide film serving as the film to be polished to a silicon nitride film serving as a polishing stopper film.

For example, a technique of raising the polishing selectivity ratio of the silicon oxide film to the silicon nitride film by introducing a polycarboxylate into the slurry is known; however, this technique is effective when a cerium oxide abrasive is used, and cannot exhibit a sufficient effect when a silicon oxide abrasive is used.

### BRIEF DESCRIPTION OF THE DRAWINGS

FIG. 1 and FIG. 2 are views showing a CMP apparatus.

FIG. 3 is a view showing an object to be polished.

FIG. 4 is a view showing changes in the torque current value.

FIG. 5 is a flowchart showing a first embodiment.

FIGS. 6 to 8 are views showing a CMP method.

FIG. 9 is a view showing an improvement in the polishing selectivity ratio.

FIG. 10 is a view showing reduction in the number of polishing scratches.

FIG. 11 is a flowchart showing a second embodiment.

FIGS. 12 to 14 are views showing a CMP method.

FIG. 15 and FIG. 16 are views showing an improvement in the flatness.

FIGS. 17 to 19 are views showing a manufacturing method of a semiconductor device.

### DETAILED DESCRIPTION

In general, according to one embodiment, a CMP method comprises: starting a polishing of a silicon oxide film by using a slurry including a silicon oxide abrasive and a polishing stopper film including a silicon nitride film, and stopping the polishing when the polishing stopper is exposed, wherein the slurry includes a first water-soluble polymer with a weight-average molecular weight of 50000 or more and 5000000 or less, and a second water-soluble polymer with a weight-average molecular weight of 1000 or more and 10000 or less.

Hereinafter, embodiments will be described with reference to the drawings.

A CMP method of an embodiment is applied to a process of carrying out planarization of a silicon oxide film (film to be polished) by using a slurry containing therein a silicon oxide abrasive, and using a silicon nitride film as a polishing stopper film. For example, in the manufacturing method of a semiconductor device, although a process of embedding a silicon oxide film in a trench of a semiconductor substrate is known, the CMP method of the embodiment is used in such a process.

In this case, in the embodiment, first and second water-soluble polymers having different molecular weight values are further contained in the CMP slurry.

The first water-soluble polymer has a weight-average molecular weight of 50000 or more and 5000000 or less, and the second water-soluble polymer has a weight-average molecular weight of 1000 or more and 10000 or less. The first and second water-soluble polymers are selected from a group constituted of, for example, polyacrylic acid, polymethacrylic acid, polysulphonic acid, and their salts.

According to the above-mentioned configuration, it is possible to reduce the polishing scratches on the surface of the silicon oxide film (film to be polished) by using the silicon oxide abrasive. Further, by containing the first water-soluble polymer in the slurry, it is possible to improve the polishing rate of the silicon oxide film. Further, by containing the second water-soluble polymer in the slurry, it is possible to secure the polishing selectivity ratio of the silicon oxide film to the silicon nitride film serving as the polishing stopper film.

### [CMP Apparatus]

First, a CMP apparatus configured to carry out the CMP method of the embodiment will be described below.

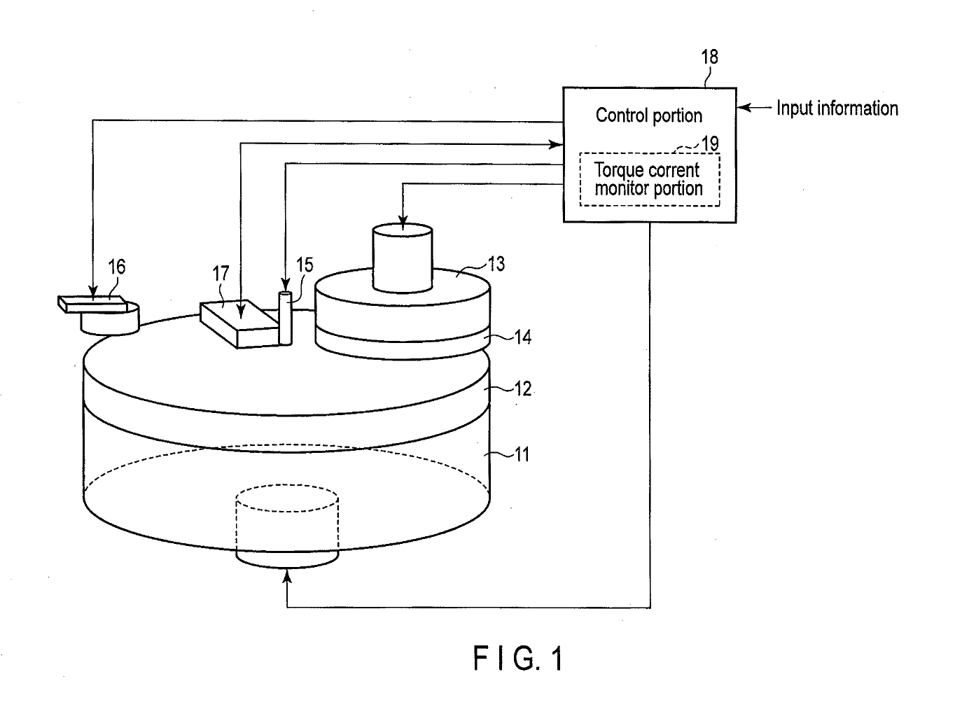

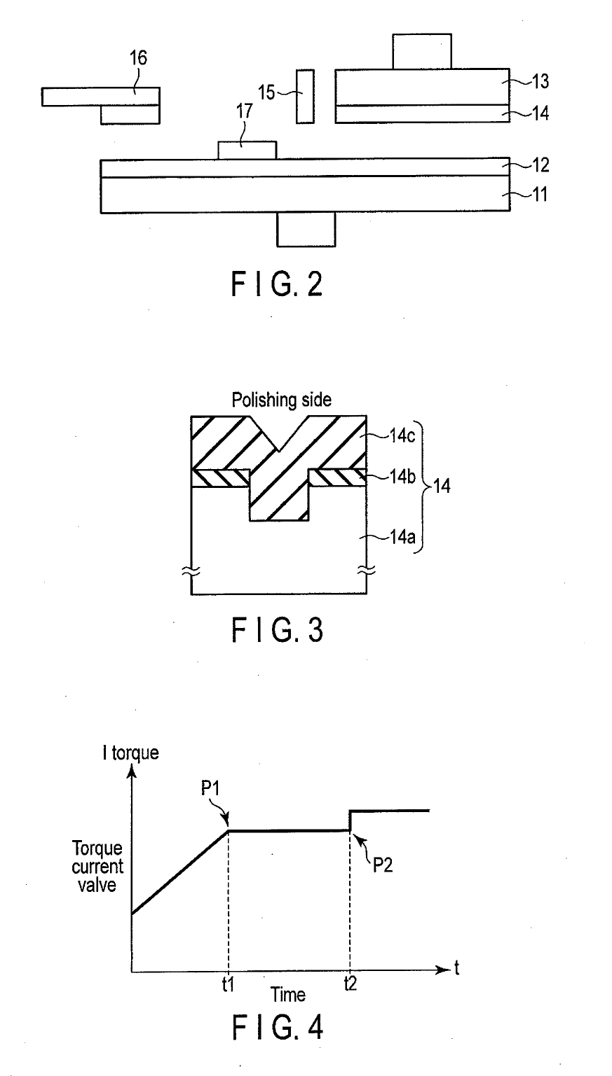

FIG. 1 and FIG. 2 show the CMP apparatus.

FIG. 1 is a perspective view of the CMP apparatus, and FIG. 2 is a side view of the CMP apparatus of FIG. 1. Stage portion (for example, a rotating table) 11 is, for example, rotationally driven (clockwise/counterclockwise). Polishing pad 12 is mounted on stage portion 11.

Holding portion 13 holds object to be polished (for example, a semiconductor wafer) 14, and brings object to be polished 14 into contact with a surface portion of polishing pad 12 in a state where holding portion 13 holds object to be polished 14. Holding portion 13 is, for example, rotationally driven (clockwise/counterclockwise).

It is desirable that both of stage portion 11 and object to be polished 14 be rotationally driven from the viewpoint of eliminating nonuniformity in the polishing amount of object to be polished 14. When both of them are rotationally driven, it is desirable that the rotational direction of holding portion 13, and that of stage portion 11 be identical to each other.

Here, it is desirable for the polishing pressure of object to be polished 14 to be, for example, 100 hPa (hectopascals) or more and 500 hPa or less. Further, it is desirable for the rotational speed of stage portion 11 or holding portion 13 to be, for example, 30 rpm (revolutions per minute) or more and 120 rpm or less.

Object to be polished 14 is, for example, as shown in FIG. 3, a semiconductor wafer (semiconductor device). Here, a semiconductor device provided with semiconductor substrate 14a, silicon nitride film 14b serving as a polishing stopper film on semiconductor substrate 14a, and silicon oxide film 14c serving as a film to be polished embedded in a trench of semiconductor substrate 14a is shown as an example of object to be polished 14.

Supplying portion 15 is arranged above stage portion 11, i.e., above, when stage portion 11 has a circular cylindrical shape, a central portion of the circle, and supplies slurry to the surface portion of polishing pad 12. The slurry contains therein, for example, a chemical solution serving as an abrasive, water, and the like.

Surface conditioning portion 16 has a function of restoring the surface portion of polishing pad 12 clogged with the silicon oxide abrasive produced by the polishing of object to be polished 14 or contained in the slurry to the initial state thereof before the polishing of object to be polished is carried out. Surface conditioning portion 16 restores the surface portion of polishing pad 12 to the initial state thereof by cutting the surface portion of polishing pad 12 by a predetermined amount.

It should be noted that surface conditioning portion 16 may restore the surface portion of polishing pad 12 to the initial state thereof each time one CMP process is completed or may restore the surface portion of polishing pad 12 to the initial state thereof after several CMP processes are carried out.

Temperature setting portion 17 is arranged on the surface portion of polishing pad 12, and sets the temperature of the surface portion of polishing pad 12, i.e., the temperature of the polishing surface of object to be polished 14. Temperature setting portion 17 is provided with, for example, a heat exchanger (contact mechanism) to be brought into contact with the surface portion of polishing pad 12, noncontact mechanism configured to supply an inert gas (heat exchange gas) to the surface portion of polishing pad 12, and the like.

When temperature setting portion 17 is constituted of the heat exchanger, it is possible to secure a wide controllable temperature range of the surface portion of the polishing pad. Further, when temperature setting portion 17 is constituted of the noncontact mechanism, neither a scratch nor nonuniformity occurs in polishing pad 12, and hence as a result, it is possible to reduce polishing scratches of object to be polished 14.

Further, temperature setting portion 17 may include a temperature sensor. Further, a temperature sensor may be provided in a portion other than temperature setting portion 17, and temperature setting portion 17 may not include a temperature sensor.

Furthermore, means for indirectly controlling the temperature of the surface portion of polishing pad 12 or the temperature of the polishing surface of object to be polished 14 by controlling the temperature of stage portion 11 or holding portion 13 may be provided in place of temperature setting portion 17.

Control portion 18 controls operations of stage portion 11, holding portion 13, supplying portion 15, surface conditioning portion 16, and temperature setting portion 17. Control portion 18 includes torque current-monitor portion 19.

Torque current-monitor portion 19 monitors a value of the torque current configured to rotationally drive stage portion 11 or holding portion 13. That is, when each of stage portion 11 and holding portion 13 is driven at a given rotational speed, it is possible to determine the point in time (polishing completion time point) at which the silicon nitride film serving as the polishing stopper film is exposed by monitoring the torque current value.

This is because, for example, when object to be polished 14 is a semiconductor device shown in FIG. 3, in a state where unevenness of silicon oxide film 14c exists, the contact resistance between polishing pad 12 and silicon oxide film 14c is low and, in a state where the unevenness of silicon oxide film 14c is eliminated, the contact resistance between polishing pad 12 and silicon oxide film 14c is high; and furthermore the contact resistance between polishing pad 12 and silicon oxide film 14c, and the contact resistance between polishing pad 12 and silicon nitride film 14b are different from each other.

More specifically, as shown in FIG. 4, as the unevenness of silicon oxide film 14c gradually gets smaller, the contact resistance between polishing pad 12 and silicon oxide film 14c gradually becomes higher, and hence the torque current value also gradually becomes larger. Further, the torque current value becomes constant after the unevenness of silicon oxide film 14c is eliminated.

Further, after this, when silicon nitride film 14b is exposed, the contact resistance between polishing pad 12 and silicon nitride film 14b is higher than the contact resistance between polishing pad 12 and silicon oxide film 14c, and hence the torque current value becomes a little larger.

It should be noted that this torque behavior is only an example, and a torque behavior different from that described above is exhibited in some cases depending on the combination of the slurry and polishing pad or the like.

As described above, it is possible to determine the polishing completion time point by detecting the changing points P1 (time t1) and P2 (time t2) of the torque current value.

However, it is also possible to determine the polishing completion time point without providing torque current-monitor portion 19. For example, the polishing completion time point may be determined by monitoring the polishing time in the CMP process according to an empirical rule.

### [CMP Method]

A CMP method using the CMP apparatus of FIG. 1 and FIG. 2 will be described below.

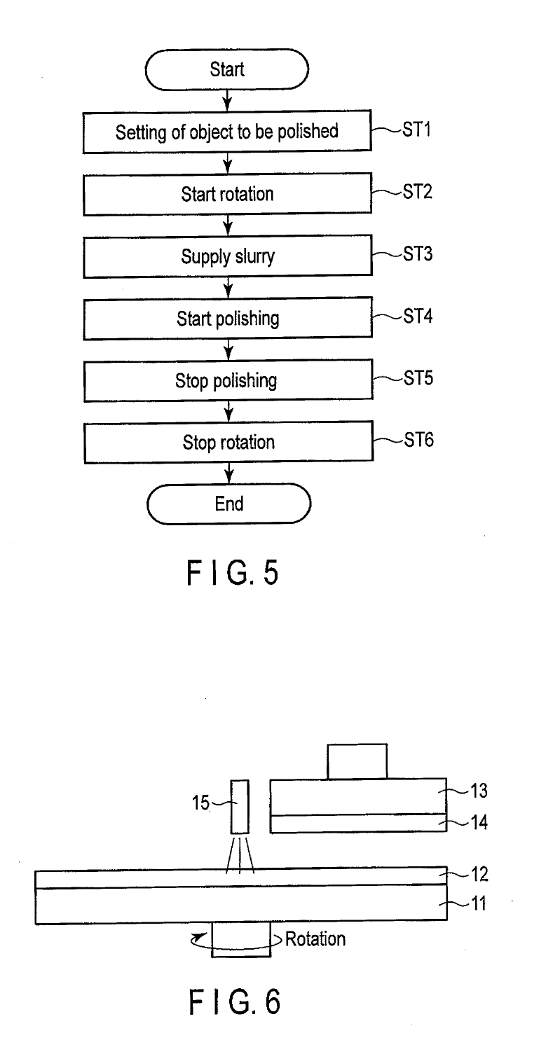

FIG. 5 shows a first embodiment of the CMP method.

This flowchart is carried out by control portion 18 of FIG. 1.

First, object to be polished 14 is set on holding portion 13 (step ST1).

This setting includes an operation of holding object to be polished 14 by holding portion 13, and operation of moving holding portion 13 to a predetermined position on stage portion 11.

Here, the object to be polished 14 is a silicon oxide film, and a silicon nitride film is used as a polishing stopper film. For example, object to be polished 14 is the semiconductor device shown in FIG. 3.

Next, rotation of stage portion 11 is started (step ST2).

Holding portion 13 may be rotated together with the rotation of stage portion 11. However, the rotation time of holding portion 13 may be identical to or different from the rotation time of stage portion 11.

Next, slurry is supplied to a portion on polishing pad 12 on stage portion 11 (step ST3).

The slurry is uniformly applied to the entire surface of polishing pad 12 by the centrifugal force.

Here, the slurry contains therein a silicon oxide abrasive. Further, the slurry contains therein a first water-soluble polymer with a weight-average molecular weight of 50000 or more and 5000000 or less, and a second water-soluble polymer with a weight-average molecular weight of 1000 or more and 10000 or less.

The first and second water-soluble polymers are selected from a group constituted of, for example, polyacrylic acid, polymethacrylic acid, polysulphonic acid, and their salts.

Here, the slurry supplying method of this embodiment is not particularly limited.

For example, a solution containing therein the silicon oxide abrasive and first and second water-soluble polymers may be supplied at a time or supply of a solution containing therein a silicon oxide abrasive, and supply of a solution containing therein the first and second water-soluble polymers may be separately carried out.

It should be noted that the molecular weight of each of the first and second water-soluble polymers can be controlled by the degree of polymerization. When the molecular weight is within each of the above-mentioned ranges, the type of the first water-soluble polymer, and the type of the second water-soluble polymer may be identical to or different from each other.

The state where steps ST1 to ST3 are completed is shown in FIG. 6.

Next, object to be polished 14 held by holding portion 13 is brought into contact with polishing pad 12, and polishing of object to be polished 14, i.e., polishing of the silicon oxide film is started (step ST4).

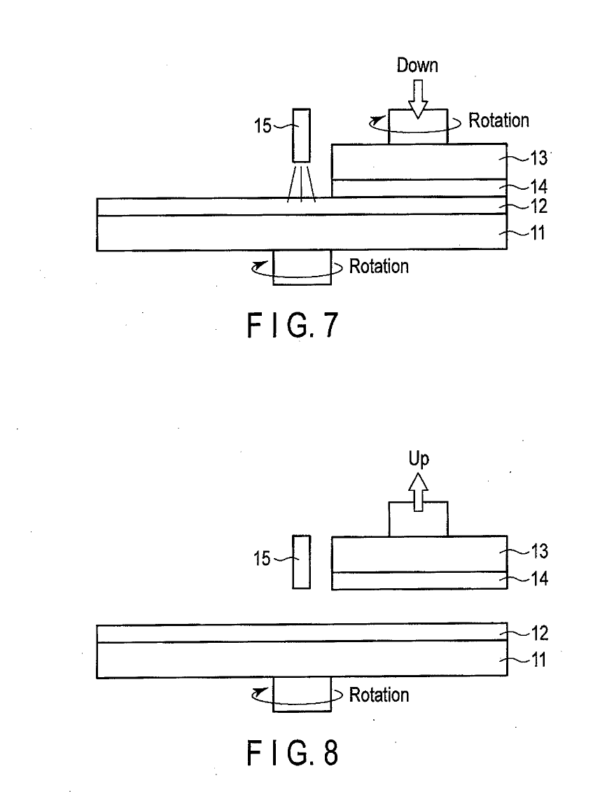

Starting of the polishing can be carried out by, for example, lowering of holding portion 13. The state of step ST4 is shown in FIG. 7.

Next, the polishing is terminated at a point in time at which the silicon nitride film serving as the polishing stopper film is exposed (step ST5).

Termination of the polishing can be carried out by, for example, raising holding portion 13.

It should be noted that the time point at which the silicon nitride film is exposed may be determined, as already described, by monitoring the torque current value of stage portion 11 or holding portion 13 or may be determined by monitoring the polishing time according to an empirical rule.

The state of step ST5 is shown in FIG. 8.

Finally, the rotation of stage portion 11 is stopped (step ST6).

According to the CMP method described above, it is possible to reduce polishing scratches on the surface of the silicon oxide film (film to be polished) by using the silicon oxide abrasive. Further, it is possible to improve the polishing rate of the silicon oxide film by containing the first water-soluble polymer in the slurry. Further, it is possible to secure the polishing selectivity ratio of the silicon oxide film to the silicon nitride film serving as the polishing stopper film by containing the second-water-soluble polymer in the slurry.

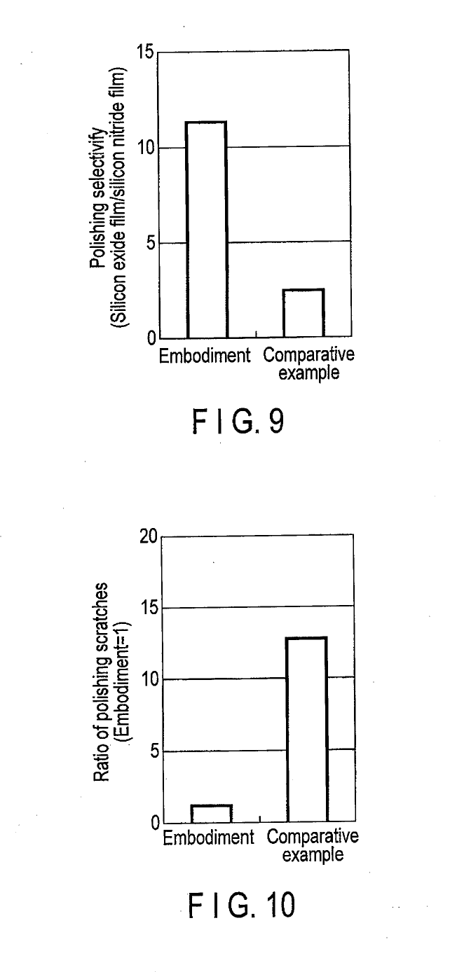

FIG. 9 shows the effect of improvement of the polishing selectivity ratio of the first embodiment.

The polishing selectivity ratio is defined as a value obtained by dividing the polishing rate of the silicon oxide film by the polishing rate of the silicon nitride film. Further, the comparative example is a result obtained when the second water-soluble polymer is removed from the slurry used in the embodiment of the above-mentioned CMP method.

As is evident from FIG. 9, the polishing selectivity ratio of the embodiment is about 11.5, whereas the polishing selectivity ratio of the comparative example is about 2.5. That is, according to the embodiment, it is possible to secure a polishing selectivity ratio about 2.5 or more times higher than that of the comparative example.

This effect can be considered to be attributable to the fact that the surface of the silicon nitride film serving as the polishing stopper film is protected by the second water-soluble polymer, and hence the probability of the silicon oxide abrasive coming into contact with the surface of the silicon nitride film decreases.

FIG. 10 shows the effect of reduction in polishing scratches of the first embodiment.

Comparison of the number of polishing scratches is carried out on the basis of the value of the comparative example obtained when the value of the embodiment is made 1. The comparative example is a result obtained when a cerium oxide abrasive is used in place of the silicon oxide abrasive contained in the slurry used in the embodiment of the above-mentioned CMP method.

As is evident from FIG. 10, assuming the number of the polishing scratches of the embodiment to be 1, the number of the polishing scratches of the comparative example is about 13. That is, according to the embodiment, it is possible to greatly reduce the number of polishing scratches formed on the surface of the silicon oxide film, which is the film to be polished, as compared with the comparative example.

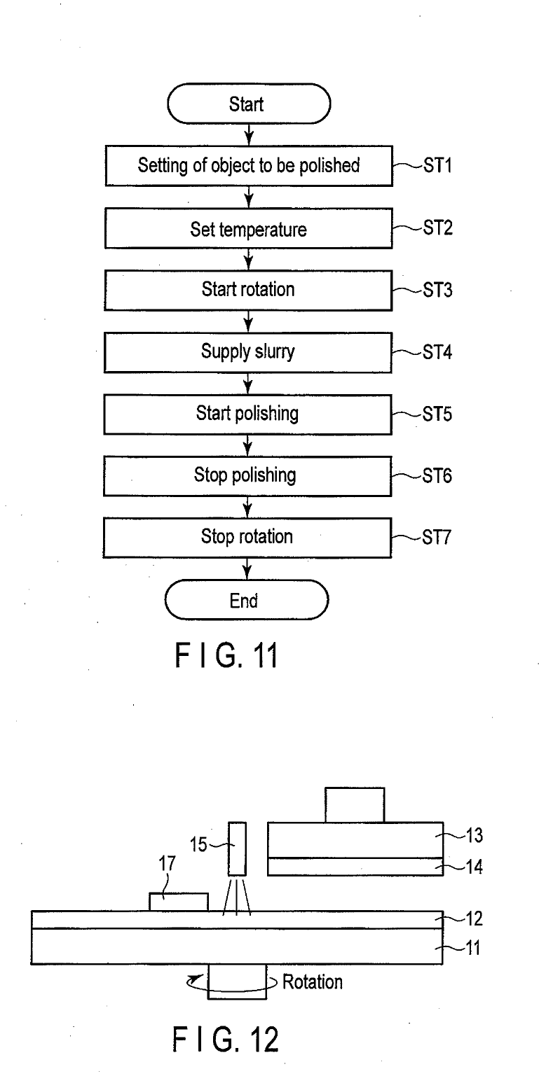

FIG. 11 shows a second embodiment of the CMP method.

This embodiment is a modification example of the first embodiment. Accordingly, a detailed description of steps identical to those of the first embodiment is omitted.

This flowchart is carried out by control portion 18 of FIG. 1.

First, object to be polished 14 is set on holding portion 13 (step ST1).

As in the first embodiment, the object to be polished 14 is a silicon oxide film, and a silicon nitride film is used as a polishing stopper film. For example, object to be polished 14 is the semiconductor device shown in FIG. 3.

Next, temperature setting is carried out (step ST2).

This step is a step newly added to this embodiment.

An object of the temperature setting is to improve the flatness of the polishing surface of the film to be polished. More specifically, the temperature of the surface portion of polishing pad 12 or the temperature of the polishing surface of object to be polished 14 is set to 40° C. or lower.

Next, rotation of stage portion 11 is started, and slurry is supplied to a portion on polishing pad 12 on stage portion 11 (steps ST3 to ST4).

The slurry contains therein a silicon oxide abrasive as in the first embodiment. Further, the slurry contains therein a first water-soluble polymer with a weight-average molecular weight of 50000 or more and 5000000 or less, and a second water-soluble polymer with a weight-average molecular weight of 1000 or more and 10000 or less.

The first and second water-soluble polymers are selected from a group constituted of, for example, polyacrylic acid, polymethacrylic acid, polysulphonic acid, and their salts.

The state where steps ST1 to ST4 are completed is shown in FIG. 12.

It should be noted that regarding the temperature setting, it is sufficient if the temperature of the surface portion of polishing pad 12 or the temperature of the polishing surface of object to be polished 14 is set to 40° C. or lower by the time immediately before the start of polishing (step ST5) to be described later. That is, the temperature setting is not conditioned to be completed between step ST1 and step ST2.

Further, even after the polishing is started, it is desirable from the viewpoint of improving the flatness of the polishing surface of the film to be polished that management be carried out in such a manner that the temperature of the surface portion of polishing pad 12 or the temperature of the polishing surface of object to be polished 14 is within the range of 40° C. or lower until the polishing is completed.

Next, object to be polished 14 held by holding portion 13 is brought into contact with polishing pad 12, and polishing of object to be polished 14, i.e., polishing of the silicon oxide film is started (step ST5).

Starting of the polishing can be carried out by, for example, lowering of holding portion 13.

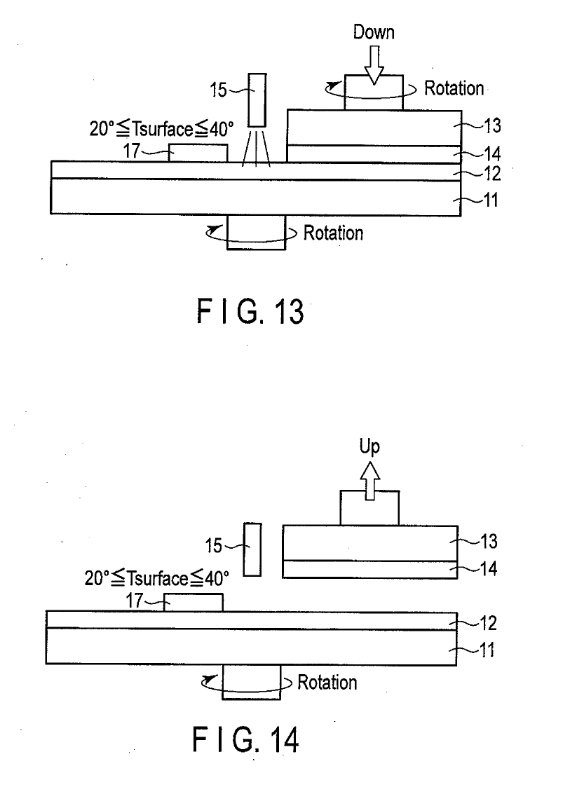

The state of step ST5 is shown in FIG. 13.

Next, the polishing is terminated at a point in time at which the silicon nitride film serving as the polishing stopper film is exposed (step ST6).

Termination of the polishing can be carried out by, for example, raising holding portion 13.

The state of step ST6 is shown in FIG. 14.

Finally, the rotation of stage portion 11 is stopped (step ST7).

According to the CMP method described above, it is possible to reduce polishing scratches on the surface of the silicon oxide film (film to be polished) by using the silicon oxide abrasive. Further, it is possible to improve the polishing rate of the silicon oxide film by containing the first water-soluble polymer in the slurry. Further, it is possible to secure the polishing selectivity ratio of the silicon oxide film to the silicon nitride film serving as the polishing stopper film by containing the second-water-soluble polymer in the slurry.

Further, it is possible to improve the flatness of the polishing surface of the film to be polished by keeping the temperature of the surface portion of polishing pad 12 or the temperature of the polishing surface of object to be polished 14 at 40° C. or lower.

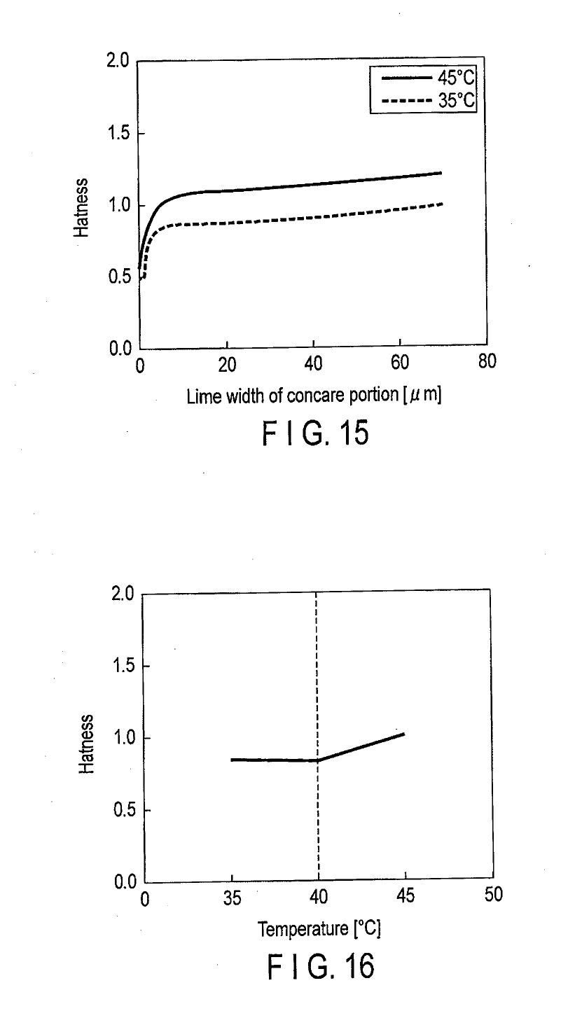

FIG. 15 and FIG. 16 show the effect of improvement of the flatness of the second embodiment.

The flatness implies a difference between the lowest point and highest point of the polishing surface of the film to be polished. That is, the flatness implies that the flatness is improved as the value thereof gets closer to zero.

In this embodiment, standardization is carried out by making the flatness obtained when the line width of the concave portion is 5 μm and the temperature is 45° C. 1.

First, according to FIG. 15, it can be seen that the flatness of the film to be polished obtained when the temperature of the surface portion of polishing pad 12 or the temperature of the polishing surface of object to be polished 14 is 35° C. is more improved than the flatness obtained when the temperature of the polishing surface is 45° C. It should be noted that in FIG. 15, the line width of the concave portion of the abscissa axis implies, for example, the width of the trench of semiconductor substrate 14a of FIG. 3.

Next, according to FIG. 16, it can be seen that the flatness of the film to be polished remarkably changes at a temperature of 40° C. of the surface portion of polishing pad 12 or the polishing surface of object to be polished, the temperature of 40° C. being the boundary between the two flatness ranges. It should be noted that although FIG. 16 shows the result obtained when the line width of the concave portion is fixed at 5 μm, similar results can be obtained for other concave portion line widths (measured data items: 0.16 μm, 0.2 μm, 0.3 μm, 1 μm, 2 μm, 10 μm, 35 μm, and 70 μm).

### [Method of Manufacturing Semiconductor Device]

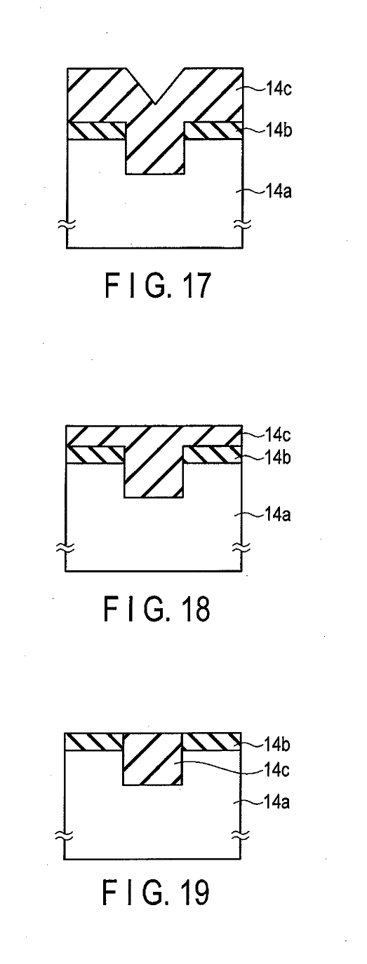

FIGS. 17 to 19 show a method of manufacturing a semiconductor device.

By applying the above-mentioned CMP method to the trench-embedding process of the manufacturing method of the semiconductor device, it is possible to realize improvement in the characteristics and manufacturing yield of the semiconductor device by the improvement in the flatness.

Hereinafter a description will be specifically given.

First, as shown in FIG. 17, silicon nitride film 14b serving as a polishing stopper film is formed on semiconductor substrate 14a. Further, a resist pattern is formed on silicon nitride film 14b by, for example, the photo engraving process (PEP). Further, by using the resist pattern as a mask, a trench (concave portion) is formed in silicon nitride film 14b and semiconductor substrate 14a by, for example, reactive ion etching (RIE). After this, the resist pattern is removed.

Further, silicon oxide film 14c configured to fill up the trench is formed on silicon nitride film 14b by, for example, chemical vapor deposition (CVD).

Next, as shown FIG. 18 and FIG. 19, silicon oxide film 14c is polished by CMP, thereby leaving silicon oxide film 14c only in the trench of semiconductor substrate 14a. The silicon oxide film 14c is polished by CMP until silicon nitride film 14b serving as the polishing stopper film is exposed.

The slurry used in CMP contains therein, as described previously, the first water-soluble polymer with a weight-average molecular weight of 50000 or more and 5000000 or less, and second water-soluble polymer with a weight-average molecular weight of 1000 or more and 10000 or less.

By the process described above, the semiconductor device according to this embodiment is completed.

It should be noted that silicon oxide film 14c remaining in the trench of semiconductor substrate 14a is used as, for example, shallow trench isolation (STI) for element isolation.

According to the embodiment, when planarization of a silicon oxide film is carried out by using a slurry containing therein a silicon oxide abrasive, it is possible to improve the polishing rate of the silicon oxide film, reduce polishing scratches thereof, and secure the polishing selectivity ratio of the silicon oxide film to the silicon nitride film serving as the polishing stopper film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A CMP method comprising:
starting a polishing of a silicon oxide film by using a slurry including a silicon oxide abrasive and a polishing stopper film including a silicon nitride film; and
stopping the polishing when the polishing stopper is exposed,
wherein the slurry includes a first water-soluble polymer with a weight-average molecular weight of 50000 or more and 5000000 or less, and a second water-soluble polymer with a weight-average molecular weight of 1000 or more and 10000 or less.

2. The method of claim 1,
wherein the first water-soluble polymer is selected from a group of polyacrylic acid, polymethacrylic acid, polysulfone acid and a chloride thereof.

3. The method of claim 1,
wherein the second water-soluble polymer is selected from a group of polyacrylic acid, polymethacrylic acid, polysulfone acid and a chloride thereof.

4. The method of claim 1,
wherein a polishing surface of the silicon oxide film has a temperature of 40° C. or less.

5. A CMP apparatus comprising:
a supplying portion supplying a slurry to a surface portion of a polishing pad, the slurry including a silicon oxide abrasive, a first water-soluble polymer with a weight-average molecular weight of 50000 or more and 5000000 or less, and a second water-soluble polymer with a weight-average molecular weight of 1000 or more and 10000 or less;
a holding portion contacting a semiconductor substrate having a silicon oxide film and a silicon nitride film with the surface portion of the polishing pad in a condition of holding the semiconductor substrate; and
a control portion which is configured to start a polishing of the silicon oxide film by using the slurry, and stop the polishing when the silicon nitride film as a polishing stopper film is exposed.

6. The apparatus of claim 5,
wherein the first water-soluble polymer is selected from a group of polyacrylic acid, polymethacrylic acid, polysulfone acid and a chloride thereof.

7. The apparatus of claim 5,
wherein the second water-soluble polymer is selected from a group of polyacrylic acid, polymethacrylic acid, polysulfone acid and a chloride thereof.

8. The apparatus of claim 5, further comprising
a temperature setting portion on the surface portion of the polishing pad, the temperature setting portion setting a temperature of the surface of the polishing pad.

9. The apparatus of claim 8,
wherein the surface of the polishing pad has a temperature of 40° C. or less.

10. The apparatus of claim 8,
wherein the temperature setting portion includes a heat exchanger in contact with the surface portion of the polishing pad.

11. The apparatus of claim 8,
wherein the temperature setting portion includes a mechanism that supplies an inert gas to the surface portion of the polishing pad.

12. The apparatus of claim 5, further comprising
a stage portion on which the polishing pad is mounted,
wherein the holding portion and the stage portion are driven to rotate.

13. The apparatus of claim 12,
wherein the control portion is configured to stop the polishing based on a torque current value of one of the stage portion and the holding portion.

14. The apparatus of claim 5, further comprising
a surface conditioning portion which conditions a state of the surface portion of the polishing pad.

15. A method of manufacturing a semiconductor device, the method comprising:
forming a silicon nitride film as a polishing stopper film on a semiconductor substrate;
forming a trench in the semiconductor substrate and the silicon nitride film;
forming a silicon oxide film on the silicon nitride film to fill the trench with the silicon oxide film;
starting a polishing of the silicon oxide film by a CMP method using a slurry including a silicon oxide abrasive, a first water-soluble polymer with a weight-average molecular weight of 50000 or more and 5000000 or less, and a second water-soluble polymer with a weight-average molecular weight of 1000 or more and 10000 or less; and
stopping the polishing when the silicon nitride film as the polishing stopper film is exposed.

16. The method of claim 15,
wherein the trench is used for an element isolation.

17. The method of claim 15,
wherein the silicon oxide film remains in the trench by the CMP method.

18. The method of claim 15,
wherein the first water-soluble polymer is selected from a group of polyacrylic acid, polymethacrylic acid, polysulfone acid and a chloride thereof.

19. The method of claim 15,
wherein the second water-soluble polymer is selected from a group of polyacrylic acid, polymethacrylic acid, polysulfone acid and a chloride thereof.

20. The method of claim 1,
wherein a polishing surface of the silicon oxide film has a temperature of 40° C. or less.
